(19) United States
(12) Patent Application Publication
(10) Pub. No.: US 2016/0247886 A1
(43) Pub. Date: Aug. 25, 2016

(54) SEMICONDUCTOR TEMPLATE AND MANUFACTURING METHOD THEREOF

(71) Applicant: Hermes-Epitek Corp., Taipei City (TW)

(72) Inventors: Po-Jung LIN, Hsinchu City (TW); Chih-Sheng WU, Taichung City (TW); Takashi KOBAYASHI, Hsinchu City (TW); Bu-Chin CHUNG, Taipei City (TW)

(21) Appl. No.: 14/626,165

(22) Filed: Feb. 19, 2015

(51) Int. Cl. H01L 29/20; H01L 21/304; H01L 21/02

(52) U.S. Cl. CPC H01L 29/2003; H01L 21/02381; H01L 21/02458; H01L 21/02502; H01L 21/0254; H01L 21/304

(57) ABSTRACT

The present invention provides a semiconductor template, comprising: a substrate; a buffer layer, disposed on a surface of the substrate and comprises a first sub-buffer layer and a second sub-buffer layer sequentially stacked, wherein the buffer layer has irregular cracks such that the top surface of the buffer layer is discontinuous, and the depth of the cracks are greater than or equal to the thickness of the second sub-buffer layer and less than or equal to sum of the thickness of the first sub-buffer and the second sub-buffer layer; and an epitaxial layer, which is a continuous layer and disposed on the buffer layer.

### BACKGROUND OF THE INVENTION

1. Field of the Invention

The present invention is related to a semiconductor template and the manufacturing method thereof, particularly to a semiconductor template with cracks on the buffer layer and the manufacturing method thereof.

2. Description of the Prior Art

Recently, growing of gallium nitride (GaN) epitaxial layers on silicon (Si) substrate is one of the popular technologies. Since the difference of thermal expansion coefficients between GaN epitaxial layers and Si substrate, it is easy to get cracks on the surface of GaN epitaxial layers by tensile stress during cooling down process. This phenomenon becomes serious on larger size wafer; therefore, it is important to control the GaN epitaxial layer stress to avoid cracks production.

When growing GaN epitaxial layer on AlN layer, the GaN epitaxial layer may grow without cracks because of the compressive stress due to the difference of the lattice constant between GaN epitaxial layer and AlN layer, the compressive stress may offset the tensile stress produced by cooling down process. Besides the problem of crack, the AlN layer between GaN epitaxial layer and Si substrate may effectively prevent the occurrence of “melting back” when growing GaN epitaxial layer directly on Si substrate. However, the structure of buffer layers made of AlN combined with other materials are complicated, such as multilayers, super-lattice layers, insertion layers, grading layers and transition layers, so as manufacturing costs may increase.

In summary, it is now a current goal to develop a method for growing of GaN epitaxial layers with high quality on Si substrate.

### SUMMARY OF THE INVENTION

One of the aspects of the present invention is directed for a semiconductor template, comprising: a substrate; a buffer layer, disposed on a surface of the substrate and comprises a first sub-buffer layer and a second sub-buffer layer sequentially stacked, wherein the buffer layer has irregular cracks such that the top surface of the buffer layer is discontinuous, and the depth of the cracks are greater than or equal to the thickness of the second sub-buffer layer and less than or equal to sum of the thickness of the first sub-buffer and the second sub-buffer layer; and an GaN epitaxial layer, which is a continuous layer and disposed on the buffer layer.

The other aspect of the present invention is providing a manufacturing method of a semiconductor template, comprising: providing a substrate; forming a first sub-buffer layer on the substrate; forming a second sub-buffer layer on the first sub-buffer layer, wherein the first sub-buffer layer and the second sub-buffer layer form a buffer; cracking the buffer layer to form irregular cracks so as to discontinue the top surface of the buffer layer, wherein the depth of the cracks are greater than or equal to the thickness of the second sub-buffer layer and less than or equal to sum of the thickness of the first sub-buffer and the second sub-buffer layer; and forming a continuing GaN epitaxial layer on the buffer layer.

The purpose, technical content, characteristic and effect of the present invention will be easy to understand by reference to the following detailed descriptions, when taken in conjunction with the accompanying drawings and the particular embodiment.

### BRIEF DESCRIPTION OF THE DRAWINGS

FIG. 1 is a schematic diagram according to the embodiment of the present invention, wherein (b) part is a cross-section view of the semiconductor template, and (a) part is a top view of the second buffer.

FIG. 2 is a flow chart of the manufacturing method of the semiconductor substrate according to the embodiment of the present invention.

### DESCRIPTION OF THE PREFERRED EMBODIMENT

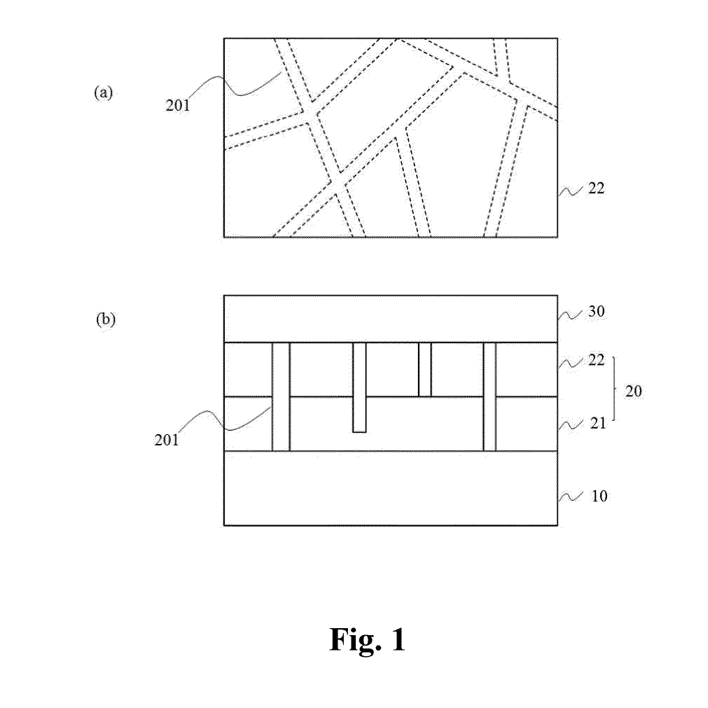

Please refer to FIG. 1, the semiconductor template according to the embodiment of the present invention comprises: a substrate 10; a buffer layer 20 disposed on a surface of the substrate 10; and an epitaxial layer 30 disposed on the buffer layer 20.

Wherein, the buffer 20 comprises a first sub-buffer layer 21 and a second sub-buffer layer 22 sequentially stacked. The buffer layer 20 shown in FIG. 1 is exemplary illustrated as two layers, that is, the first sub-buffer layer and the second sub-buffer layer 22, but the present invention is not limited thereto, the buffer layer may comprise a plurality of layer if needed.

The buffer 20 has irregular cracks 201 such that the top surface of the buffer layer is discontinuous. The term “irregular cracks” means that the cracks are naturally created by thermal stress without any artificial processing (for example, etching method or slicing method, etc), and the cracks are formed as random patterns, as shown in (a) part of FIG. 1. Herein, since the second buffer is the layer inside the semiconductor template, the cracks in (a) part of FIG. 1 is illustrated by dot line,

In detail, the depth of the cracks 201 are greater than or equal to the thickness of the second sub-buffer layer 22 and less than or equal to sum of the thickness of the first sub-buffer 21 and the second sub-buffer layer 22, as shown in (b) part of FIG. 1. That is, the irregular cracks may completely or partially penetrate one of the first sub-buffer layer and the second sub-buffer layer, or the cracks may penetrate both the first sub-buffer layer and the second sub-buffer layer simultaneously, so as to discontinuous the top surface of the buffer layers. It is noted that the cracks may not extend to the substrate or the epitaxial layer, so as to provide high quality of the manufacturing process.

Wherein, the cracks may construct a plurality of gaps inside the buffer layer in the following manufacturing process, such that the opposite inner side walls of the cracks are separated. Because of the gaps generated by the cracks in the buffer layers, the stress during cooling down process may be absorbed and the cracks on the surface of the epitaxial layer may be avoided.

The thermal expansion coefficient of the first sub-buffer layer 21 and the second sub-buffer layer 22 are different from that of the substrate 10, in particular, the thermal expansion coefficient of the first sub-buffer layer 21 and the second sub-buffer layer 22 are different. Because gallium may interact with silicon substrate and produce meltback etching effect, the first sub-buffer layer 21 may not comprise gallium. For example, the first sub-buffer layer comprises aluminum nitride (AlN) and the second sub-buffer layer 22 comprises aluminum gallium nitride (AlGaN) or gallium nitride (GaN).

The epitaxial layer 30 is a continuous layer, that is, the epitaxial layer 30 has no cracks. The epitaxial layer 30 comprises nitride; preferably, the epitaxial layer 30 comprises gallium nitride (GaN).

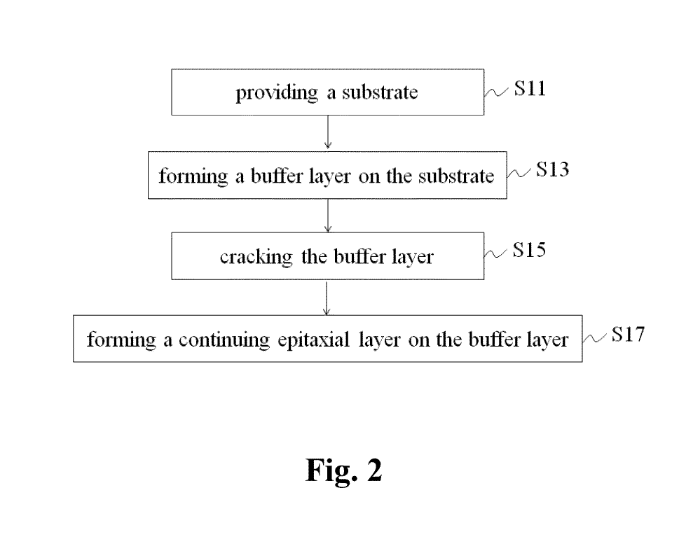

Next, the manufacturing method of the semiconductor template as above would be described as follows clearly referring to FIG. 2.

As shown in FIG. 2, the manufacturing method of the semiconductor template comprises: providing a substrate (step S11), the substrate may comprise silicon substrate. And then, forming a buffer layer on the substrate (step S13), wherein, the step of forming the buffer layer comprises forming a first sub-buffer layer on the substrate and then forming a second sub-buffer layer on the first sub-buffer layer. Wherein, the number of the buffer layer may not be limited thereto, the buffer layer may comprise more than two sun-buffer layers.

The step of forming the buffer layer may be process in the temperature of 900-1200° C., perfectly, in the temperature of 1000-1100° C., perfectly, in the temperature of 1050° C., but not limited to the present invention.

It is noted that, the thermal expansion coefficient of the first sub-buffer and the second sub-buffer layer are different from the substrate, in particular, the thermal expansion coefficient of the first sub-buffer layer and the second sub-buffer layer are different. For example, the first sub-buffer layer may comprise aluminum nitride (AlN) and the second sub-buffer layer may comprise aluminum gallium nitride (AlGaN) or gallium nitride (GaN).

Next, as shown in step S15, the buffer layer is cracked to form irregular cracks, so that the top surface of the buffer layer is discontinued. Herein, the step of cracking of the buffer layer is realized by cooling or mechanical force. For example, the mechanical force comprises the tensile stress produced by the difference of the thermal expansion coefficient. In particular, in the embodiment of the present, the buffer layer is cracked by a cooling treatment in the temperature of 400-700° C., perfectly, in the temperature of 500-600° C.

Since the thermal expansion coefficient of the first sub-buffer and the second sub-buffer layer are different from the substrate, the buffer layers are easy to get cracks on the surface by tensile stress during heating and cooling process. Wherein, the depth of the cracks are greater than or equal to the thickness of the second sub-buffer layer and less than or equal to sum of the thickness of the first sub-buffer and the second sub-buffer layer.

Finally, as step S17, a GaN epitaxial layer is formed on the buffer layer. Herein, the GaN epitaxial layer is grown on the patterned buffer layer and filled up the cracks by epitaxial lateral overgrowth (ELOG) technology. The GaN epitaxial layer is grown in the temperature of 900-1200° C., perfectly, in the temperature of 1000-1100° C., perfectly, in the temperature of 1050° C., but not limited to the present invention. After the heating process, the semiconductor substrate is cooling down to the room temperature and the semiconductor template of the present invention is obtained.

According to the manufacturing method of the semiconductor substrate as described above, the cracks of the buffer layers are naturally created by thermal stress. Because of the patterned buffer layer, that is, the buffer layer having cracks, the stress of the GaN epitaxial layer grown on the said patterned buffer layer may be separated and absorbed by the cracks during cooling down process. Therefore, the GaN epitaxial layer may be avoid generating cracks on the surface and growth as a continuous layer. By doing so, the semiconductor template according the present invention may provide GaN epitaxial layer with high quality on Si substrate.

In summary, the traditional methods for growing GaN epitaxial layer on Si substrate usually use AlN combined with other materials to form various buffer structures to control stress; however, the said buffer structures are complicated and with higher manufacturing costs. The semiconductor template and the manufacturing method thereof of the present invention provides with advantages such as simple structure to control the tensile stress during growth process, low cost, so as may improve lacks of prior art.

The embodiments as above only illustrate the technical concepts and characteristics of the present invention; it is purposed for person ordinary skill in the art to understand and implement the present invention, but not for the limitation to claims of the present invention. That is, any equivalent change or modification in accordance with the spirit of the present invention should be covered by the appended claims.

What is claimed is:

1. A semiconductor template, comprising:
a substrate;
a buffer layer, disposed on a surface of the substrate and comprises a first sub-buffer layer and a second sub-buffer layer sequentially stacked, wherein the buffer layer has irregular cracks such that an top surface of the buffer layer is discontinuous, and the depth of the cracks are greater than or equal to the thickness of the second sub-buffer layer and less than or equal to sum of the thickness of the first sub-buffer and the second sub-buffer layer; and
an epitaxial layer, which is a continuous layer and disposed on the buffer layer.

2. The semiconductor template as claim 1, wherein the opposite inner side walls of the cracks are separated.

3. The semiconductor template as claim 1, wherein the thermal expansion coefficient of the first sub-buffer layer and the second sub-buffer layer are different from the thermal expansion coefficient of the substrate.

4. The semiconductor template as claim 1, wherein the thermal expansion coefficient of the first sub-buffer layer and the second sub-buffer layer are different.

5. The semiconductor template as claim 1, wherein the first sub-buffer layer comprises aluminum nitride.

6. The semiconductor template as claim 1, wherein the second sub-buffer layer comprises aluminum gallium nitride or gallium nitride.

7. The semiconductor template as claim 1, wherein the epitaxial layer comprises nitride.

8. The semiconductor template as claim 1, wherein the epitaxial layer comprises gallium nitride.

9. The semiconductor template as claim 1, wherein the substrate comprises a silicon substrate.

10. A manufacturing method of a semiconductor template, comprising:
providing a substrate;
forming a first sub-buffer layer on the substrate;
forming a second sub-buffer layer on the first sub-buffer layer, wherein the first sub-buffer layer and the second sub-buffer layer form a buffer layer;
cracking the buffer layer to form irregular cracks so as to discontinue an top surface of the buffer layer, wherein the depth of the cracks are greater than or equal to the thickness of the second sub-buffer layer and less than or equal to sum of the thickness of the first sub-buffer and the second sub-buffer layer; and
forming a continuing epitaxial layer on the buffer layer.

11. The manufacturing method of the semiconductor template as claim 10, wherein the opposite inner side walls of the cracks are separated.

12. The manufacturing method of the semiconductor template as claim 10, wherein the cracking of the buffer layer is realized by mechanical force produced by the difference of thermal expansion coefficient of the buffer layer.

13. The manufacturing method of the semiconductor template as claim 10, wherein the forming of the first sub-buffer layer and the second sub-buffer layer is process in the temperature of 900-1200° C.

14. The manufacturing method of the semiconductor template as claim 10, the cracking of the buffer layer is process in the temperature of 400-700° C.

15. The manufacturing method of the semiconductor template as claim 10, wherein the thermal expansion coefficient of the first sub-buffer and the second sub-buffer layer are different from the thermal expansion coefficient of the substrate.

16. The manufacturing method of the semiconductor template as claim 10, wherein the thermal expansion coefficient of the first sub-buffer and the second sub-buffer layer are different.

17. The manufacturing method of the semiconductor template as claim 10, wherein the forming of the epitaxial layer is process in the temperature of 900-1200° C.

18. The manufacturing method of the semiconductor template as claim 10, wherein the first sub-buffer layer comprises aluminum nitride.

19. The manufacturing method of the semiconductor template as claim 10, wherein the second sub-buffer layer comprises aluminum gallium nitride or gallium nitride.

20. The manufacturing method of the semiconductor template as claim 10, wherein the epitaxial layer comprises nitride.

21. The manufacturing method of the semiconductor template as claim 10, wherein the epitaxial layer comprises gallium nitride.

22. The manufacturing method of the semiconductor template as claim 10, wherein the substrate comprises a silicon substrate.
